(19) United States
(12) Patent Application Publication
(10) Pub. No.: US 2025/0016993 A1
(43) Pub. Date: Jan. 9, 2025

(54) SEMICONDUCTOR DEVICE

(71) Applicant: SAMSUNG ELECTRONICS CO., LTD., Suwon-si (KR)

(72) Inventors: Sung-Hwan JANG, Suwon-si (KR); Guifu YANG, Suwon-si (KR); Jinbum KIM, Suwon-si (KR); Sunguk JANG, Suwon-si (KR)

(21) Appl. No.: 18/428,207

(22) Filed: Jan. 31, 2024

(30) Foreign Application Priority Data
Jul. 3, 2023 (KR) 10-2023-0085901

(51) Int. Cl. H10B 12/00

(52) U.S. Cl. CPC H10B 12/485; H10B 12/315; H10B 12/482; H10B 12/488

(57) ABSTRACT

A semiconductor device includes a substrate including a recess region; a bit line contact in the recess region; a bit line on the bit line contact, the bit line extending in a first direction; a first insulating pattern covering side surfaces of the bit line contact and an inner surface of the recess region; and a second insulating pattern on the first insulating pattern, wherein an oxygen density of the first insulating pattern is higher than an oxygen density of the second insulating pattern.

### CROSS-REFERENCE TO RELATED APPLICATIONS

This U.S. non-provisional patent application claims priority under 35 U.S.C. § 119 to Korean Patent Application No. 10-2023-0085901, filed on Jul. 3, 2023, in the Korean Intellectual Property Office, the entire contents of which are hereby incorporated by reference.

### BACKGROUND

### 1 Field

Embodiments relate to a semiconductor device.

### 2. Description of the Related Art

Due to their small-sized, multifunctional, and/or low-cost characteristics, semiconductor devices are being esteemed as important elements in the electronics industry. The semiconductor devices may include a semiconductor memory device for storing data, a semiconductor logic device for processing data, or a hybrid semiconductor device including both of memory and logic elements.

Due to the recent increasing demand for electronic devices with a fast speed and/or low power consumption, the semiconductor device may have a fast operating speed and/or a low operating voltage.

### SUMMARY

The embodiments may be realized by providing a semiconductor device including a substrate including a recess region; a bit line contact in the recess region; a bit line on the bit line contact, the bit line extending in a first direction; a first insulating pattern covering side surfaces of the bit line contact and an inner surface of the recess region; and a second insulating pattern on the first insulating pattern, wherein an oxygen density of the first insulating pattern is higher than an oxygen density of the second insulating pattern.

The embodiments may be realized by providing a semiconductor device including a substrate including an active pattern; a bit line on the active pattern, the bit line extending in a first direction; a bit line contact between the bit line and the active pattern; a storage node contact on the active pattern and spaced apart from the bit line and the bit line contact; and a dipole formation structure between a side surface of the bit line contact and the storage node contact, the dipole formation structure including a first insulating pattern and a second insulating pattern, wherein the second insulating pattern includes a metal oxide.

The embodiments may be realized by providing a semiconductor device including active patterns, each active pattern including edge portions and a center portion between the edge portions; bit lines on the center portions, the bit lines extending in a first direction; bit line contacts between the center portions and the bit lines; word lines extending in a second direction and crossing the active patterns, the second direction intersecting the first direction; data storage patterns on the edge portions, respectively; storage node contacts between the edge portions and the data storage patterns; and dipole formation structures between side surfaces of the bit line contacts and the storage node contacts, wherein each of the dipole formation structures includes a first insulating pattern and a second insulating pattern, which are in contact with each other, the bit line contact includes doped poly silicon, and the second insulating pattern includes a metal oxide.

### BRIEF DESCRIPTION OF THE DRAWINGS

Features will be apparent to those of skill in the art by describing in detail exemplary embodiments with reference to the attached drawings in which:

FIG. 1 is a block diagram illustrating a semiconductor device according to an embodiment.

FIG. 2 is a plan view illustrating a portion (e.g., P1 of FIG. 1) of a semiconductor device according to an embodiment.

FIGS. 3 and 4 are sectional views, which are taken along lines A-A′ and B-B′ of FIG. 2 to illustrate a semiconductor device according to an embodiment.

FIGS. 5A to 5C are enlarged sectional views illustrating a portion (e.g., P2 of FIG. 3) of a semiconductor device according to an embodiment.

FIGS. 6A to 11C are diagrams of stages in a method of fabricating a semiconductor device, according to an embodiment.

### DETAILED DESCRIPTION

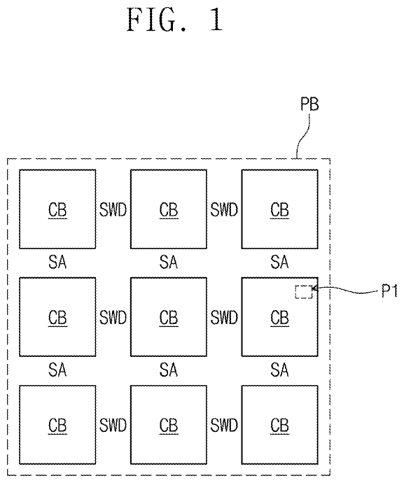

FIG. 1 is a block diagram illustrating a semiconductor device according to an embodiment.

Referring to FIG. 1, a semiconductor device may include cell blocks CB and a peripheral block PB, which may enclose each of the cell blocks CB. Each of the cell blocks CB may include a cell circuit (e.g., a memory integrated circuit). The peripheral block PB may include various peripheral circuits, which may be for operations of the cell circuit, and the peripheral circuits may be electrically connected to the cell circuit.

The peripheral block PB may include sense amplifier circuits SA and sub-word line driver circuits SWD. In an implementation, the sense amplifier circuits SA may face each other, with the cell blocks CB therebetween, and the sub-word line driver circuits SWD may face each other, with the cell blocks CB therebetween. The peripheral block PB may further include power and ground driver circuits, which may be used to drive a sense amplifier.

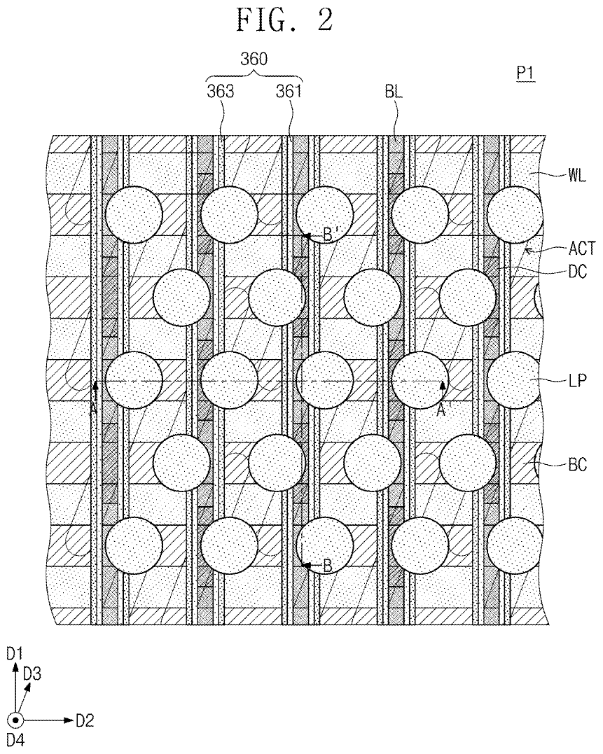

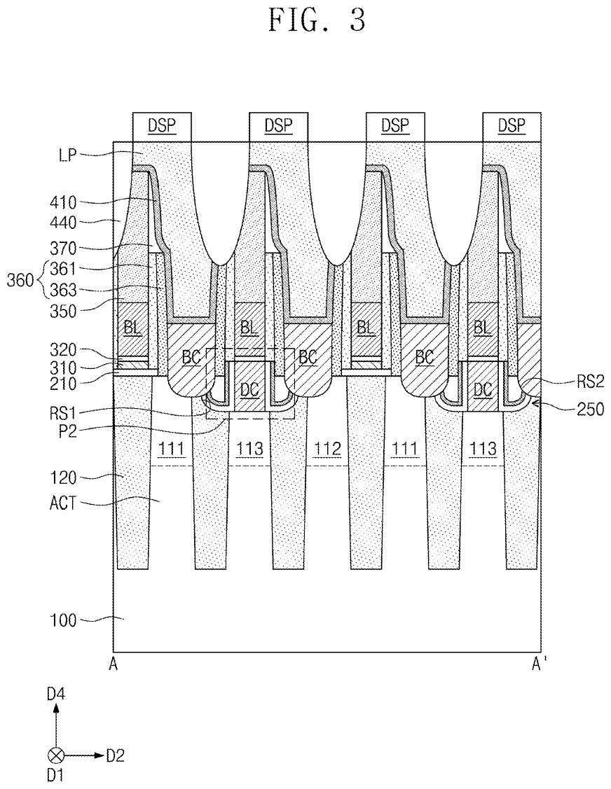

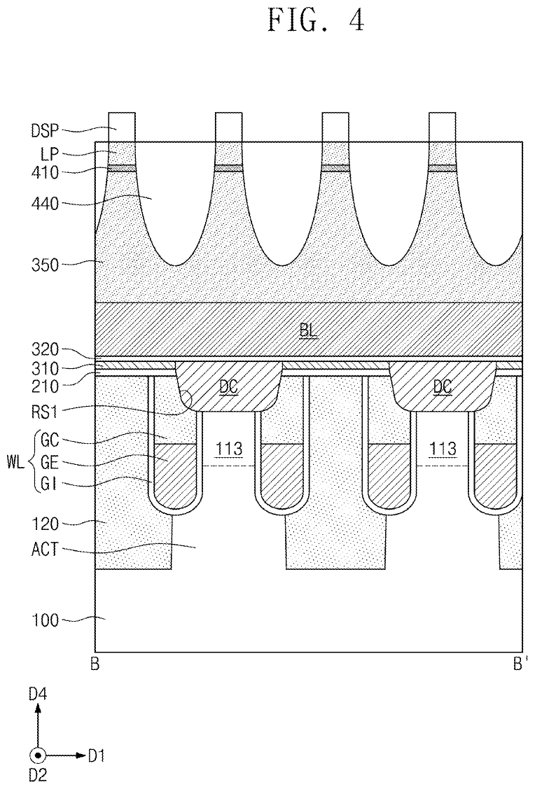

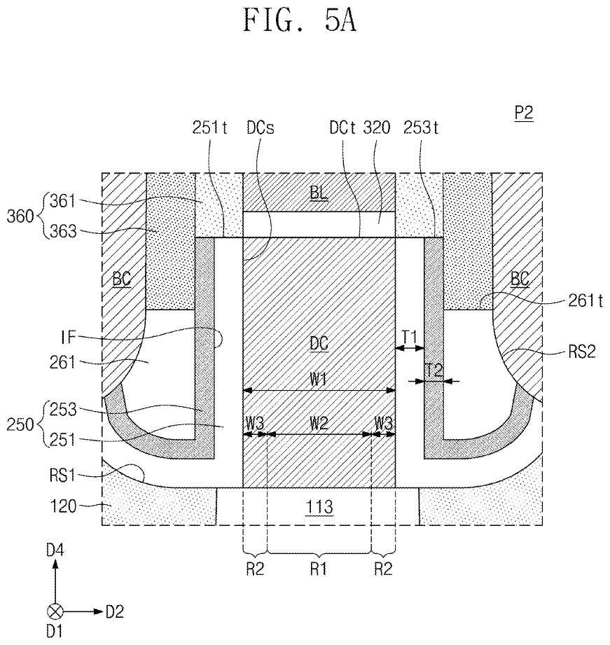

FIG. 2 is a plan view illustrating a portion (e.g., P1 of FIG. 1) of a semiconductor device according to an embodiment. FIGS. 3 and 4 are sectional views, which are taken along lines A-A′ and B-B′ of FIG. 2 to illustrate a semiconductor device according to an embodiment.

Referring to FIGS. 2 to 4, a substrate 100 may be provided. The substrate 100 may be a semiconductor substrate. In an implementation, the semiconductor substrate may include a silicon substrate, a germanium substrate, or a silicon-germanium substrate.

A device isolation pattern 120 may be in the substrate 100 to define active patterns ACT. The active patterns ACT may be spaced apart from each other in a first direction D1 and a second direction D2, which are not parallel to each other. The first and second directions D1 and D2 may be parallel to a bottom surface of the substrate 100.

The active patterns ACT may be isolated bar-shaped patterns, which are spaced apart from each other and extend (e.g., lengthwise) in a third direction D3. The third direction D3 may be parallel to the bottom surface of the substrate 100 and may not be parallel to the first and second directions D1 and D2. When viewed in a plan view, the active patterns ACT may be portions of the substrate 100 enclosed by the device isolation pattern 120. The active patterns ACT may be a protruding pattern that is extended in a fourth direction D4, which is perpendicular to the bottom surface of the substrate 100. The device isolation pattern 120 may include an insulating material. In an implementation, the insulating material may be at least one of silicon oxide, silicon nitride, or combinations thereof. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

Each of the active patterns ACT may include a pair of edge portions 111 and 112 and a center portion 113. The pair of edge portions 111 and 112 may include a first edge portion 111 and a second edge portion 112. The first edge portion 111 may be one of end portions of the active pattern ACT in the third direction D3. The second edge portion 112 may be the other of the end portions of the active pattern ACT in the third direction D3. The center portion 113 may be a portion of the active pattern ACT, which is between the pair of edge portions 111 and 112 and, e.g., between an adjacent pair of word lines WL to be described below. Each of top surfaces of the pair of edge portions 111 and 112 may be at a level higher than a top surface of the center portion 113. The pair of edge portions 111 and 112 and the center portion 113 may be doped with impurities (e.g., n- or p-type impurities).

The word line WL may be in the active patterns ACT. In an implementation, a plurality of word lines WL may be provided. The word lines WL may extend in the second direction D2 and may be spaced apart from each other in the first direction D1. The word lines WL may be in trenches, which may be in the active patterns ACT and the device isolation pattern 120. In an implementation, the pair of word lines WL, which may be adjacent to each other in the first direction D1, may cross one active pattern ACT.

Each of the word lines WL may include a gate electrode GE, a gate dielectric pattern GI, and a gate capping pattern GC. The gate electrode GE may penetrate the active patterns ACT and the device isolation pattern 120 in the second direction D2. The gate dielectric pattern GI may be between the gate electrode GE and the active patterns ACT and between the gate electrode GE and the device isolation pattern 120. The gate capping pattern GC may be on the gate electrode GE and may cover a top surface of the gate electrode GE.

Each of first recess regions RS1 may be on the center portion 113 of each of the active patterns ACT. The first recess regions RS1 may expose top surfaces of the center portions 113 of the active patterns ACT, a portion of the device isolation pattern 120, and portions of the gate capping patterns GC of the word lines WL.

A buffer pattern 210 may be on the substrate 100. The buffer pattern 210 may cover a portion of the active pattern ACT, a portion of the device isolation pattern 120, and a portion of the word line WL. The buffer pattern 210 may not be on the center portions 113 of the active patterns ACT. In an implementation, the buffer pattern 210 may be formed of or include, e.g., silicon oxide, silicon nitride, silicon oxynitride, or combinations thereof.

A bit line BL may be on the device isolation pattern 120 and the active patterns ACT. In an implementation, a plurality of bit lines BL may be provided. The bit lines BL may extend in the first direction D1 and may be spaced apart from each other in the second direction D2. Each of the bit lines BL may be on the center portions 113 of the active patterns ACT, which may be arranged in the first direction D1, and may extend in the first direction D1. The bit lines BL may be formed of or include, e.g., a metallic material or a metal. In an implementation, the bit line BL may be formed of or include, e.g., tungsten, rubidium, molybdenum, titanium, or combinations thereof.

A bit line contact DC may be on each of the active patterns ACT. In an implementation, a plurality of bit line contacts DC may be provided. The bit line contacts DC may be on and connected to the center portions 113 of the active patterns ACT, respectively. The bit line contacts DC may be spaced apart from each other in the first and second directions D1 and D2. The bit line contacts DC may be between the center portions 113 of the active patterns ACT and the bit lines BL. The bit line contacts DC may electrically connect the bit lines BL to corresponding ones of the center portions 113. The bit line contacts DC may be formed of or include, e.g., doped or undoped polysilicon, metallic materials, or combinations thereof. In an implementation, the bit line contacts DC may be formed of or include poly silicon that is doped with n-type impurities.

The bit line contacts DC may be in the first recess regions RS1, respectively. The bit line contacts DC may partially fill the first recess regions RS1. A width of the bit line contact DC in the second direction D2 may be smaller than a width of the bit line contact DC in the first direction D1. When viewed in a plan view, the bit line contact DC may have, e.g., a rectangular shape. Portions of the bit line contacts DC may be in contact with a dipole formation structure 250, which will be described below.

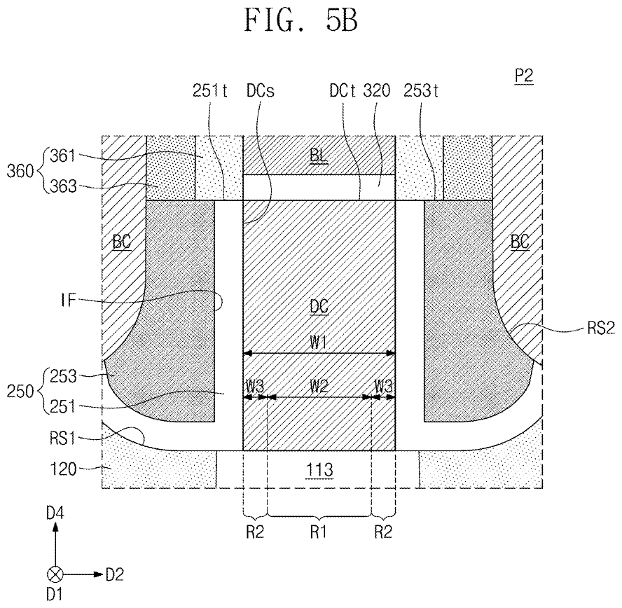

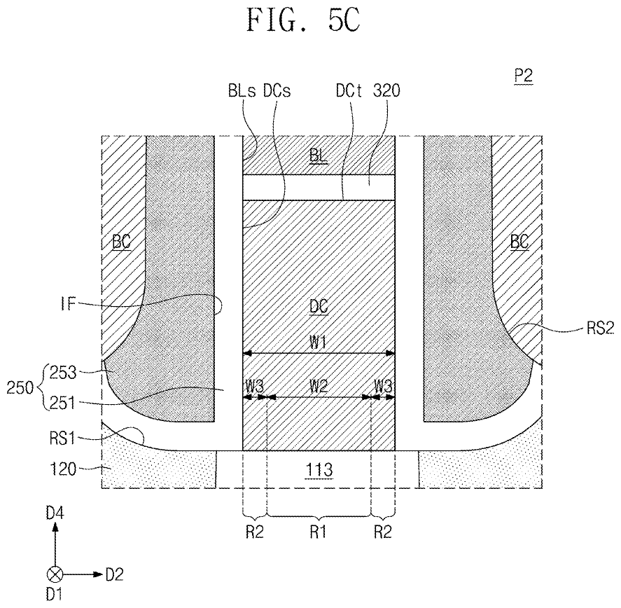

The dipole formation structure 250 may be on a side surface of the bit line contact DC. In an implementation, the dipole formation structure 250 may be in the first recess region RS1. The dipole formation structure 250, along with the bit line contact DC, may fill the first recess region RS1. In an implementation, a plurality of dipole formation structures 250 may be provided. The dipole formation structures 250 may be on opposite side surfaces of the bit line contact DC and may extend in the first direction D1. A length of the dipole formation structure 250 in the first direction D1 may be substantially equal to a length of the bit line contact DC in the first direction D1. The dipole formation structures 250 may be spaced apart from each other in the second direction D2. Hereinafter, the dipole formation structure 250 will be described in detail with reference to FIGS. 5A to 5C.

A polysilicon pattern 310 may be between the bit line BL and the buffer pattern 210 and between the bit line contacts DC, which are adjacent to each other in the first direction D1. The polysilicon pattern 310 may be in contact with each of the bit line contacts DC, which are adjacent to each other in the first direction D1. In an implementation, a plurality of polysilicon patterns 310 may be provided. A top surface of the polysilicon pattern 310 may be at substantially the same level as a top surface of the bit line contact DC. In an implementation, the polysilicon pattern 310 may be formed of or include poly silicon.

First ohmic patterns 320 may be between the bit line BL and the bit line contacts DC and between the bit line BL and the polysilicon patterns 310. The first ohmic patterns 320 may extend along the bit lines BL and in the first direction D1 and may be spaced apart from each other in the second direction D2. In an implementation, the first ohmic patterns 320 may be formed of or include a metal silicide.

A first barrier pattern may be further included between the first ohmic pattern 320 and the bit line BL. The first barrier pattern may be formed of or include a conductive metal nitride (e.g., titanium nitride or tantalum nitride).

Bit line capping patterns 350 may be on top surfaces of the bit lines BL, respectively. The bit line capping patterns 350 may extend in the first direction D1 and along corresponding ones of the bit lines BL and may be spaced apart from each other in the second direction D2. When viewed in a plan view, the bit line capping patterns 350 may be vertically overlapped with the bit lines BL, respectively. The bit line capping patterns 350 may be composed of a single layer or a plurality of layers. In an implementation, the bit line capping patterns 350 may be formed of or include silicon nitride.

Bit line spacers 360 may be on side surfaces of the bit lines BL and side surfaces of the bit line capping patterns 350. The bit line spacers 360 may cover the side surfaces of the bit lines BL and the side surfaces of the bit line capping patterns 350. In an implementation, each of the bit line spacers 360 may extend from the side surface of the bit line BL to the side surface of the bit line capping pattern 350.

Each of the bit line spacers 360 may include a plurality of spacers. In an implementation, each of the bit line spacers 360 may include a first bit line spacer 361 and a second bit line spacer 363. The second bit line spacer 363 may be on the side surface of the bit line BL and the side surface of the bit line capping pattern 350. The first bit line spacer 361 may be between the bit line BL and the second bit line spacer 363 and between the bit line capping pattern 350 and the second bit line spacer 363. In an implementation, each of the first and second bit line spacers 361 and 363 may be formed of or include silicon nitride, silicon oxide, or silicon oxynitride.

A capping spacer 370 may be placed on the bit line spacer 360. In an implementation, the capping spacer 370 may cover a top surface of the second bit line spacer 363 and a side surface of the first bit line spacer 361. The capping spacer 370 may be formed of or include, e.g., silicon nitride.

A storage node contact BC may be between the bit lines BL, which are adjacent to each other in the second direction D2. In an implementation, a plurality of storage node contacts BC may be provided. The storage node contacts BC may be spaced apart from each other in the first and second directions D1 and D2. The storage node contacts BC, which are adjacent to each other in the first direction D1, may be spaced apart from each other with the word line WL therebetween. The storage node contacts BC, which are adjacent to each other in the second direction D2, may be spaced apart from each other with the bit line BL therebetween. The storage node contacts BC may fill second recess regions RS2, respectively, which are formed on the edge portions 111 and 112 of the active patterns ACT, and may be connected to the edge portions 111 and 112, respectively. In an implementation, the storage node contacts BC may be formed of or include doped or undoped polysilicon, a metallic material, or combinations thereof.

A second barrier pattern 410 may conformally cover the bit line spacer 360, the storage node contact BC, and the bit line capping pattern 350. In an implementation, the second barrier pattern 410 may be formed of or include a conductive metal nitride (e.g., titanium nitride and tantalum nitride).

A second ohmic pattern may be further included between the second barrier pattern 410 and the storage node contact BC. In an implementation, the second ohmic pattern may be formed of or include a metal silicide.

A landing pad LP may be on the storage node contact BC. In an implementation, a plurality of landing pads LP may be provided, and here, the landing pads LP may be spaced apart from each other in the first and second directions D1 and D2. The landing pads LP may be connected to the storage node contacts BC, respectively. A lower region of the landing pad LP may be vertically overlapped with the storage node contact BC. An upper region of the landing pad LP may be shifted from the lower region in the second direction D2. A portion of the upper region of the landing pad LP may be on a top surface of the bit line capping pattern 350. In an implementation, the landing pad LP may be formed of or include a metallic material (e.g., tungsten, titanium, or tantalum).

A filler pattern 440 may enclose side surfaces of the landing pad LP. The filler pattern 440 may be between the landing pads LP, which are adjacent to each other in the first and second directions D1 and D2. When viewed in a plan view, the filler pattern 440 may have a mesh shape with holes, and in this case, the landing pads LP may be in the holes to penetrate the filler pattern 440. In an implementation, the filler pattern 440 may be formed of or include silicon nitride, silicon oxide, silicon oxynitride, or combinations thereof. In an implementation, the filler pattern 440 may include an empty space with an air layer (e.g., an air gap).

A data storage pattern DSP may be on the landing pad LP. In an implementation, a plurality of data storage patterns DSP may be provided, and the data storage patterns DSP may be spaced apart from each other in the first and second directions D1 and D2. Each of the data storage patterns DSP may be connected to a corresponding one of the edge portions 111 and 112 of the active patterns ACT through a corresponding one of the landing pads LP and a corresponding one of the storage node contacts BC.

In an implementation, the data storage pattern DSP may be a capacitor including a bottom electrode, a dielectric layer, and a top electrode. In this case, the semiconductor memory device according to an embodiment may be a dynamic random access memory (DRAM) device. In an implementation, the data storage pattern DSP may include a magnetic tunnel junction pattern. In this case, the semiconductor memory device may be a magnetic random access memory (MRAM) device. In an implementation, the data storage pattern DSP may include a phase-changeable material or a variable resistance material. In this case, the semiconductor memory device may be a phase-change random access memory (PRAM) device or a resistive random access memory (ReRAM) device. In an implementation, the data storage pattern DSP may include various structures and/or materials which can be used to store data.

FIGS. 5A to 5C are enlarged sectional views illustrating a portion (e.g., P2 of FIG. 3) of a semiconductor device according to an embodiment.

Referring to FIGS. 5A to 5C, the bit line contact DC may include a first region R1 and a second regions R2. The first region R1 may be between the second regions R2. In an implementation, the first region R1 may be at a center of the bit line contact DC in the second direction D2, and the second regions R2 may be adjacent to side surfaces DCs of the bit line contact DC. The bit line contact DC may have a first width W1 in the second direction D2. The first region R1 of the bit line contact DC may have a second width W2 in the second direction D2, and each of the second regions R2 of the bit line contact DC may have a third width W3 in the second direction D2. The first width W1 may be substantially equal to a sum of the second width W2 and two times the third widths W3. In an implementation, the bit line contact DC may be formed of or include n-type poly silicon.

A voltage applied to the storage node contacts BC may depend on an operation mode of the semiconductor device. In the case where the voltage of 0V is applied to the storage node contacts BC, there may be a potential difference between the storage node contacts BC and the bit line contact DC, which are adjacent to the storage node contacts BC in the second direction D2. Thus, a depletion region may be produced in portions of the bit line contact DC, which are adjacent to the storage node contacts BC. In an implementation, the second regions R2 of the bit line contact DC may correspond to the depletion region formed by the storage node contacts BC. Thus, the first region R1 of the bit line contact DC may enable the movement of electrons. The third width W3 of the second regions R2 may be constant, independent of the first width W1 of the bit line contact DC. Accordingly, as the first width W1 of the bit line contact DC (i.e., the size of the semiconductor device) decreases, the second width W2 of the first region R1 for the movement of electrons may decrease. In an implementation, a current path of the bit line contact DC may become narrow.

In an implementation, each of the dipole formation structures 250 on the side surfaces DCs of the bit line contact DC may include a first insulating pattern 251 and a second insulating pattern 253. The first insulating pattern 251 may cover the side surface DCs of the bit line contact DC and an inner surface of the first recess region RS1. In an implementation, the first insulating pattern 251 may extend from the side surface DCs of the bit line contact DC to the inner surface of the first recess region RS1. The second insulating pattern 253 may be on the first insulating pattern 251 to be in contact with the first insulating pattern 251. In this case, an interface IF may be between the first and second insulating patterns 251 and 253. The interface IF between the first and second insulating patterns 251 and 253 may extend from a region on the side surface DCs of the bit line contact DC to a region on the inner surface of the first recess region RS1. The first and second insulating patterns 251 and 253 may be formed of or include different materials from each other. In an implementation, the first insulating pattern 251 may be formed of or include a silicon-containing insulating material (e.g., SiO, SiON, SiN, SiCN, or SiBN), the second insulating pattern 253 may be formed of or include a metal-containing insulating material (e.g., lanthanum oxide (LaO) or scandium oxide (ScO)).

In an implementation, the first insulating pattern 251 may be formed of or include silicon oxide. The second insulating pattern 253 may be formed of or include a metal oxide. In this case, an oxygen density or concentration of the second insulating pattern 253 may be smaller than an oxygen density of the first insulating pattern 251. Owing to a difference in oxygen density between the first and second insulating patterns 251 and 253, an oxygen atom in the first insulating pattern 251 may move (e.g., diffuse) to the second insulating pattern 253. Thus, an electric dipole may be formed at the interface IF between the first and second insulating patterns 251 and 253.

In an implementation, positive charges may be accumulated in the first insulating pattern 251, and negative charges may be accumulated in the second insulating pattern 253. The positive charges accumulated in the first insulating pattern 251 may lead to a reduction in the size of the second (i.e., depletion) region R2, which is formed in the bit line contact DC. In an implementation, owing to the electric dipole at the interface IF between the first and second insulating patterns 251 and 253, the third width W3 of the second regions R2 of the bit line contact DC may be reduced. In an implementation, the third width W3 of the second regions R2 may be reduced without any change of the first width W1 of the bit line contact DC, and the second width W2 of the first region R1 of the bit line contact DC may be increased. This may mean an increase in the width of the electron conduction path in the bit line contact DC. As a result, the electrical characteristics of the semiconductor device may be improved.

Referring to FIG. 5A, the first and second insulating patterns 251 and 253 may have a constant or uniform thickness in the second direction D2. In an implementation, the first insulating pattern 251 may have a first thickness T1 in the second direction D2, and the second insulating pattern 253 may have a second thickness T2 in the second direction D2. The first thickness T1 may be larger than the second thickness T2, and the second thickness T2 may be equal to or smaller than about 1/10 of the first thickness T1. In an implementation, even when the second thickness T2 of the second insulating pattern 253 is smaller than the first thickness T1 of the first insulating pattern 251, an electric dipole may be between the first and second insulating patterns 251 and 253. In an implementation, the first thickness T1 may range from about 4 nm to 5 nm. The second thickness T2 may range from about 2 Å to 3 Å.

A top surface 251t of the first insulating pattern 251 may be at the same level as a top surface 253t of the second insulating pattern 253. The top surfaces 251t and 253t of the first and second insulating patterns 251 and 253 may be at the same level as a top surface DCt of the bit line contact DC. In an implementation, the top surfaces 251t and 253t of the first and second insulating patterns 251 and 253 may be coplanar with the top surface DCt of the bit line contact DC. The first bit line spacer 361 may be on the top surface 251t of the first insulating pattern 251 and the top surface 253t of the second insulating pattern 253. The dipole formation structure 250 may be in contact with the storage node contact BC, which is adjacent to the dipole formation structure 250 in the second direction D2.

An insulating gapfill pattern 261 may be on the dipole formation structure 250. The insulating gapfill pattern 261 may be in contact with the second insulating pattern 253 and may fill the first recess region RS1. In an implementation, the first recess region RS1 may be filled with the bit line contact DC, the dipole formation structure 250, and the insulating gapfill pattern 261. The insulating gapfill pattern 261 may be in contact with a portion of the storage node contact BC and a portion of the second bit line spacer 363. The insulating gapfill pattern 261 may be formed of or include a material that is different from the first and second insulating patterns 251 and 253. In an implementation, the insulating gapfill pattern 261 may be formed of or include silicon nitride, silicon oxynitride, or combinations thereof. In an implementation, the insulating gapfill pattern 261 may include an empty space with an air layer (e.g., an air gap).

In an implementation, a top surface 261t of the insulating gapfill pattern 261 may be at a level, which is lower than the top surfaces 251t and 253t of the first and second insulating patterns 251 and 253 and the top surface DCt of the bit line contact DC. In an implementation, the top surface 261t of the insulating gapfill pattern 261 may be at the same level as the top surfaces 251t and 253t of the first and second insulating patterns 251 and 253 and the top surface DCt of the bit line contact DC. In an implementation, the top surface 261t of the insulating gapfill pattern 261 may be concave toward the storage node contact BC.

Referring to FIG. 5B, the insulating gapfill pattern 261 may be omitted, and the first recess region RS1 may be filled with the second insulating pattern 253. In an implementation, the first recess region RS1 may be filled with the bit line contact DC and the dipole formation structure 250. The dipole formation structure 250 may be between the storage node contact BC and the bit line contact DC, which are adjacent to each other in the second direction D2. The second insulating pattern 253 may be in contact with the storage node contact BC, and the first insulating pattern 251 may be in contact with the bit line contact DC. The first and second bit line spacers 361 and 363 may be placed on the top surfaces 251t and 253t of the first and second insulating patterns 251 and 253.

The second insulating pattern 253 may not have a constant thickness. In an implementation, as illustrated in the drawings, the second insulating pattern 253 may be thicker than the first insulating pattern 251. In an implementation, as shown in FIG. 5A, the thickness of the first insulating pattern 251 may be larger than the thickness of the second insulating pattern 253.

Referring to FIG. 5C, the first and second bit line spacers 361 and 363 may be omitted, and the first and second insulating patterns 251 and 253 may extend to a region on a side surface BLs of the bit line BL. In an implementation, the interface IF between the first and second insulating patterns 251 and 253 may also extend to the region on the side surface BLs of the bit line BL. In an implementation, the first and second insulating patterns 251 and 253 may be used as spacer patterns for the bit line BL in the process of forming the second recess region RS2. In this case, the fabrication process of the semiconductor device may be simplified.

In an implementation, the first and second insulating patterns 251 and 253 may extend along the side surface BLs of the bit line BL and the side surface DCs of the bit line contact DC from the side surface of the bit line capping pattern 350 of FIG. 3 to the inner surface of the first recess region RS1. The top surfaces 251t and 253t of the first and second insulating patterns 251 and 253 may be between the top surface DCt of the bit line contact DC and the top surface of the bit line capping pattern 350 of FIG. 3.

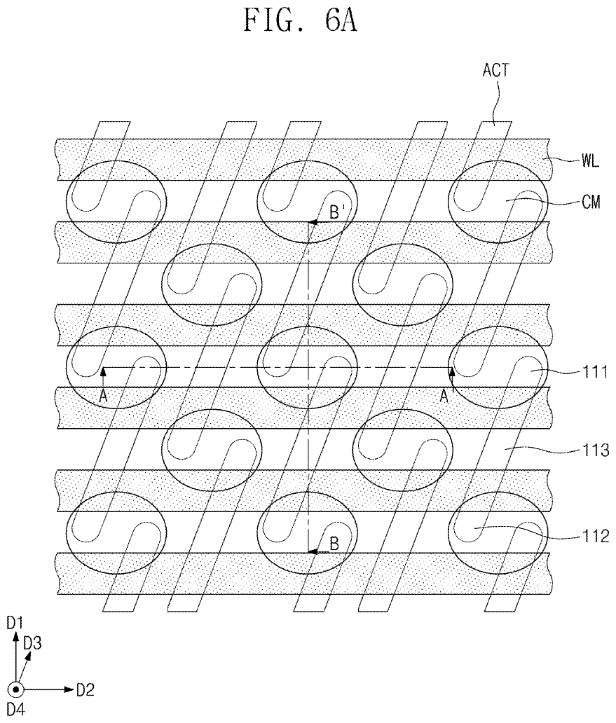

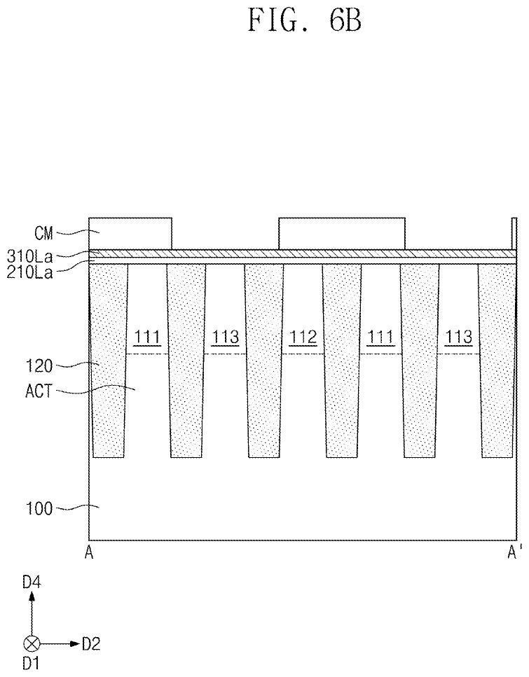

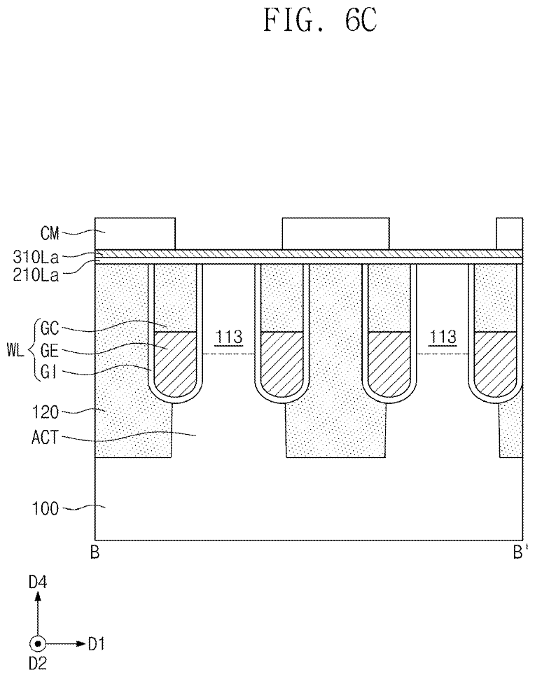

FIGS. 6A to 11C are diagrams illustrating stages in a method of fabricating a semiconductor device, according to an embodiment. In detail, FIGS. 6A, 7A, 8A, 9A, 10A, and 11A are plan views of the semiconductor device, FIGS. 6B, 7B, 8B, 9B, 10B, and 11B are sectional views taken along lines A-A′ of FIGS. 6A, 7A, 8A, 9A, 10A, and 11A, respectively, and FIGS. 6C, 7C, 8C, 9C, 10C, and 11C are sectional views taken along lines B-B′ of FIGS. 6A, 7A, 8A, 9A, 10A, and 11A, respectively.

Referring to FIGS. 6A, 6B, and 6C, the device isolation pattern 120 and the active pattern ACT may be formed in the substrate 100. The formation of the device isolation pattern 120 and the active pattern ACT may include performing a patterning process to form a groove in the substrate 100, filling the groove with an insulating material, and performing a planarization process on the insulating material to form the device isolation pattern 120. The active pattern ACT may include a portion of the substrate 100, in which the groove is not formed.

The word lines WL may be formed in trenches, which are formed in an upper portion of the substrate 100. The formation of the word lines WL may include forming mask patterns on the active patterns ACT and the device isolation pattern 120, performing an anisotropic etching process using the mask patterns to form trenches, and filling the trenches with the word lines WL. The word lines WL may be spaced apart from each other in the first direction D1 and may extend in the second direction D2 across the active patterns ACT.

In an implementation, the formation of the word lines WL may include depositing the gate dielectric pattern GI to conformally cover an inner surface of the trench, filling the trench with a conductive layer, performing an etch-back and/or polishing process on the conductive layer to form the gate electrode GE, and forming the gate capping pattern GC on the gate electrode GE to fill a remaining portion of the trench. A pair of word lines WL are placed on each of the active patterns ACT. A portion of each active pattern ACT, which is between each pair of the word lines WL, may be defined as the center portion 113. Two opposite portions of each active pattern ACT, which is spaced apart from the center portion 113 with the paired word lines WL therebetween, may be defined as the edge portions 111 and 112.

A first buffer layer 210La and a first polysilicon layer 310La may be sequentially formed on the substrate 100. The first buffer layer 210La and the first polysilicon layer 310La may cover the top surfaces of the active patterns ACT, the device isolation patterns 120, and the word lines WL.

Contact mask patterns CM may be formed on the first polysilicon layer 310La. The contact mask patterns CM may be on the edge portions 111 and 112 of the active patterns ACT and may not be on the center portions 113 of the active patterns ACT. The contact mask patterns CM may be spaced apart from each other in the first and second directions D1 and D2.

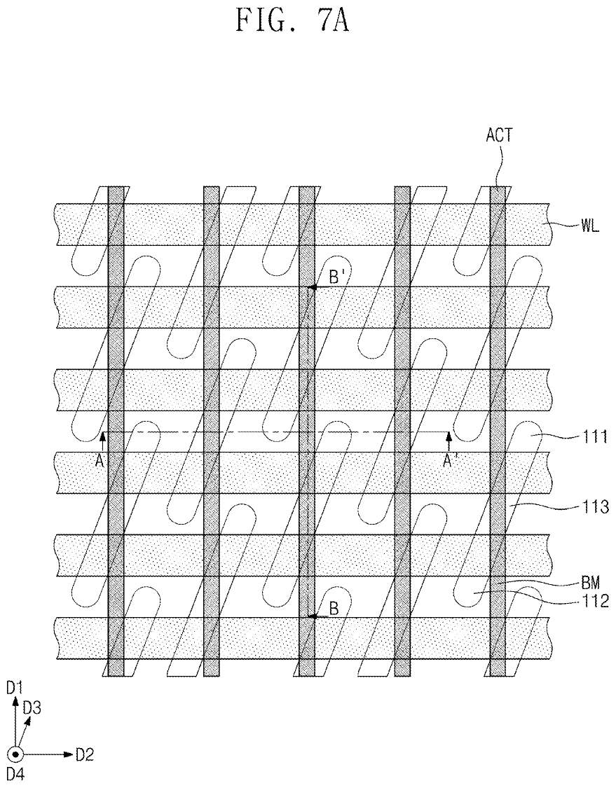

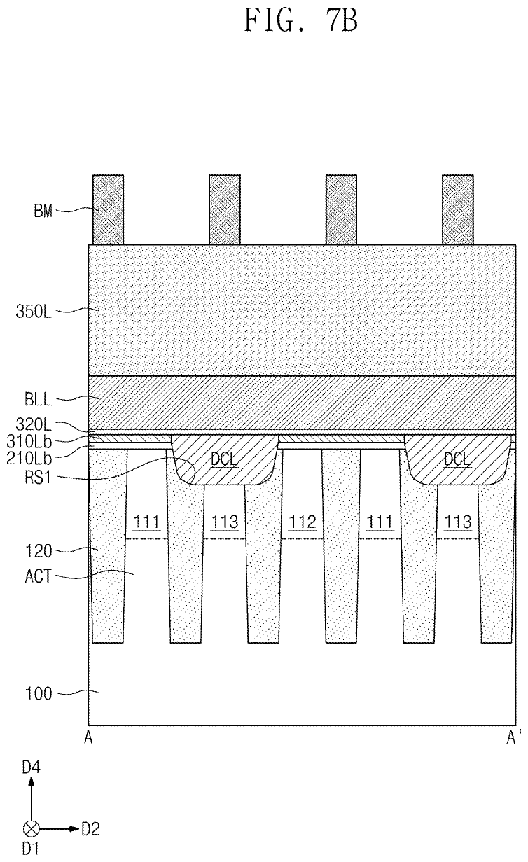

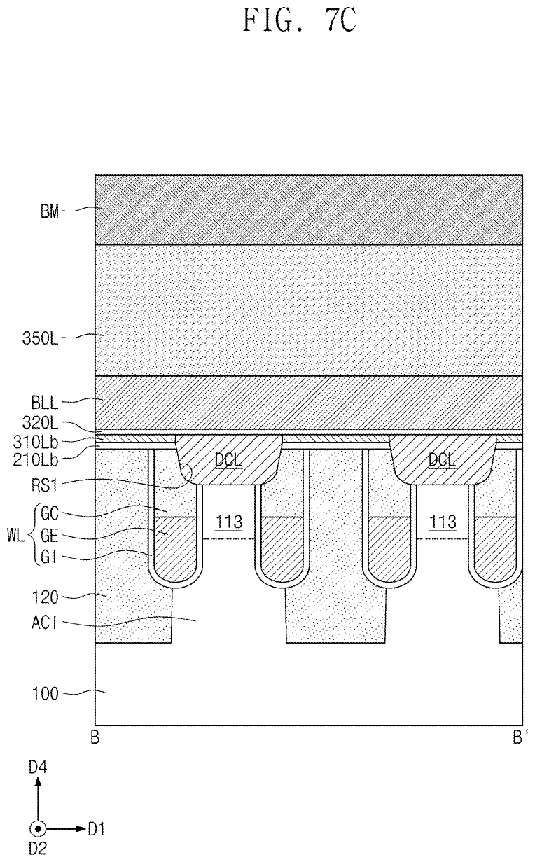

Referring to FIGS. 7A, 7B, and 7C, the first recess regions RS1 may be formed on the center portions 113 of the active patterns ACT. The formation of the first recess regions RS1 may include performing an anisotropic etching process using the contact mask patterns CM as an etch mask. The first recess region RS1 may expose the top surface of the center portion 113, a portion of the word line WL, and a portion of the device isolation pattern 120. In an implementation, a level of the top surface of the center portion 113 may be lowered by the anisotropic etching process, and in this case, the top surface of the center portion 113 may be at a level lower than the top surfaces of the edge portions 111 and 112.

The anisotropic etching process may be performed to remove a portion of the first buffer layer 210La and a portion of the first polysilicon layer 310La. Thus, a second buffer layer 210Lb and a second polysilicon layer 310Lb may be formed from the first buffer layer 210La and the first polysilicon layer 310La, respectively.

Thereafter, bit line contact lines DCL may be formed to fill the first recess regions RS1, respectively. The formation of the bit line contact lines DCL may include forming a bit line contact layer to cover the substrate 100 and fill the first recess regions RS1 and removing an upper portion of the bit line contact layer to expose a top surface of the second polysilicon layer 310Lb. The removal of the upper portion of the bit line contact layer may be performed using a planarization process. Since the upper portion of the bit line contact layer is removed, the bit line contact layer may form the bit line contact lines DCL, which are spaced apart from each other.

After the formation of the bit line contact lines DCL, a first ohmic layer 320L, a bit line layer BLL, a bit line capping layer 350L, and bit line mask patterns BM may be sequentially formed on the substrate 100. The bit line mask patterns BM may extend in the first direction D1 and may be spaced apart from each other in the second direction D2.

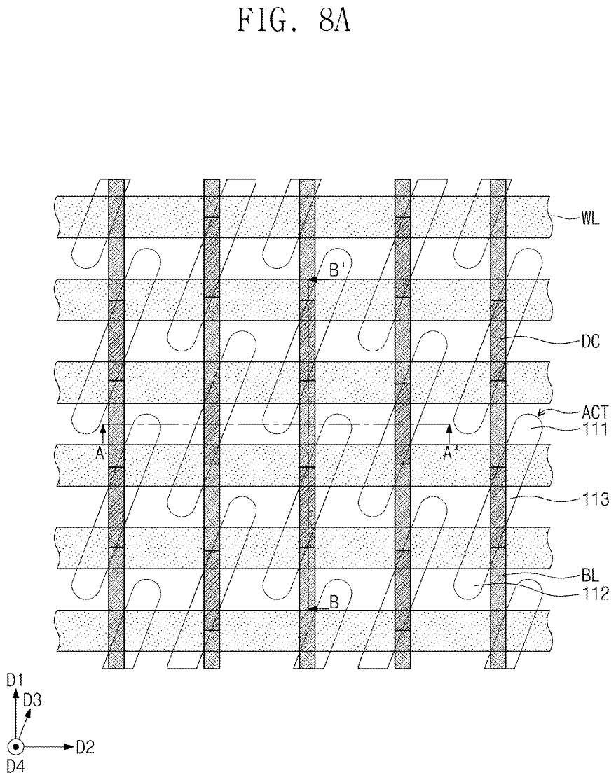

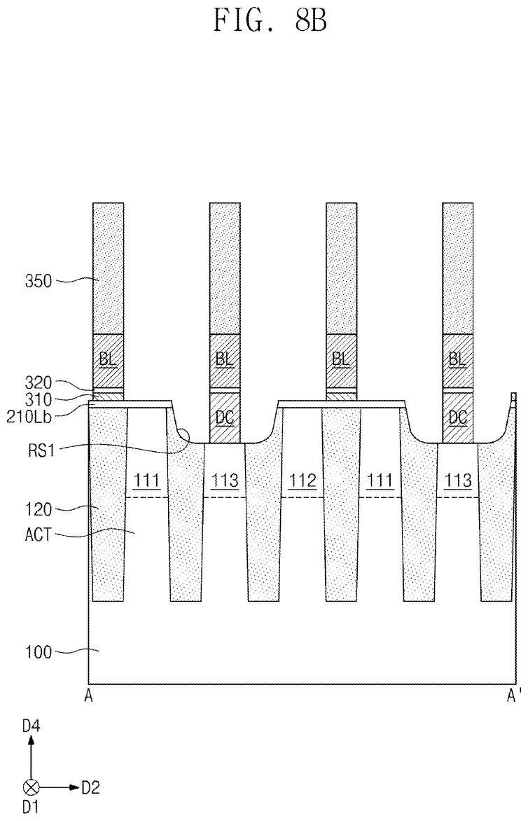

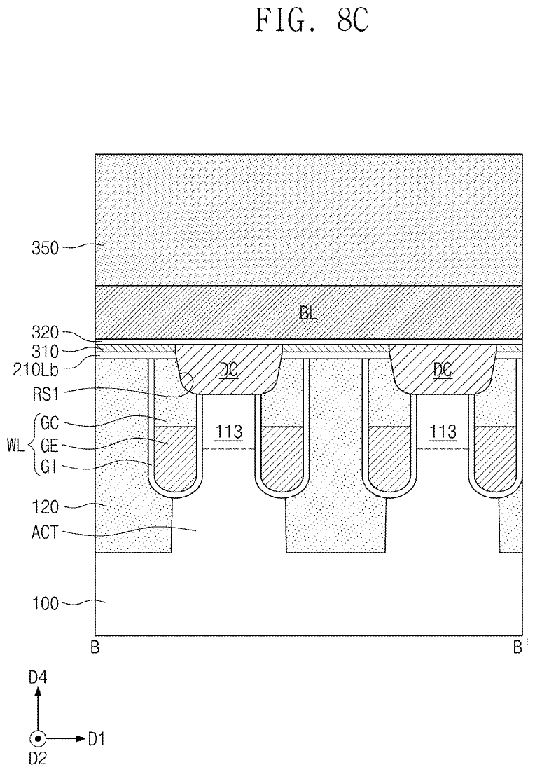

Referring to FIGS. 8A, 8B, and 8C, the bit line capping patterns 350, the bit lines BL, the first ohmic patterns 320, the bit line contacts DC, and the polysilicon patterns 310 may be formed. The formation of the bit line capping patterns 350, the bit lines BL, the first ohmic patterns 320, the bit line contacts DC, and the polysilicon patterns 310 may include performing an anisotropic etching process using the bit line mask patterns BM as an etch mask. In an implementation, the bit line capping patterns 350, the bit lines BL, the first ohmic patterns 320, the bit line contacts DC, and the polysilicon patterns 310 may be formed from the bit line capping layer 350L, the bit line layer BLL, the first ohmic layer 320L, the bit line contact line DCL, and the second polysilicon layer 310Lb, respectively.

After the anisotropic etching process, an inner surface of the first recess region RS1 may be partially exposed to the outside. In an implementation, a portion of the top surface of the center portion 113, which is not covered with the bit line contact DC, and a portion of the device isolation pattern 120 may be exposed to the outside.

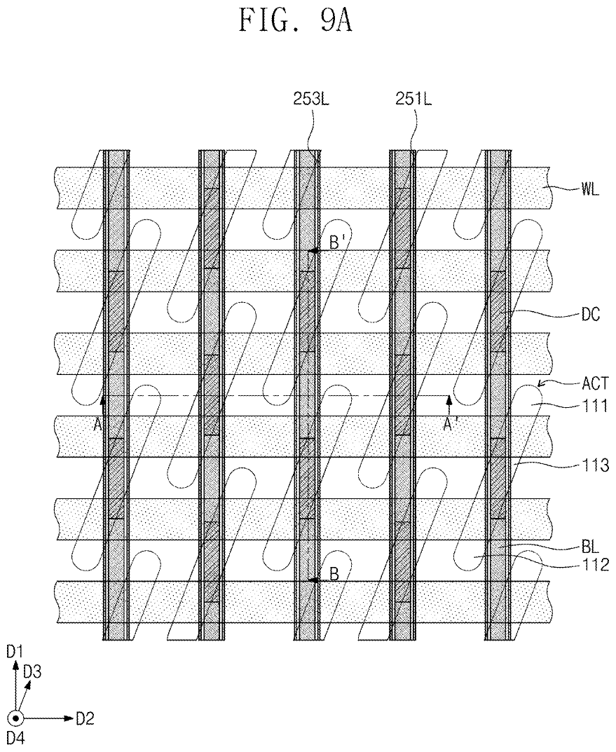

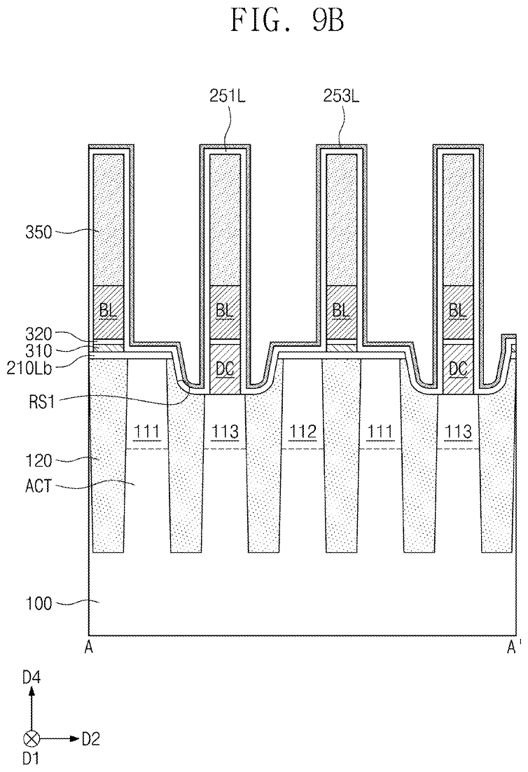

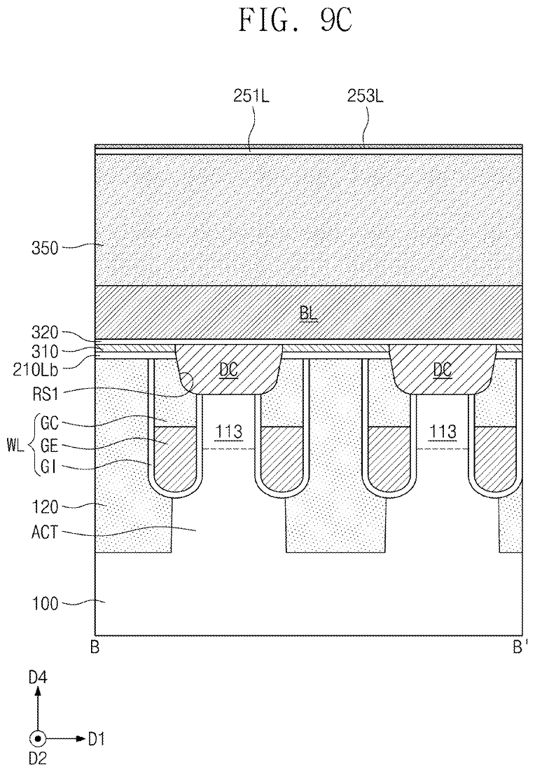

Referring to FIGS. 9A, 9B, and 9C, a first insulating layer 251L and a second insulating layer 253L may be sequentially formed. The first and second insulating layers 251L and 253L may be formed through a deposition process. In an implementation, the deposition process may include a chemical vapor deposition (CVD) process or an atomic layer deposition (ALD) process.

The first insulating layer 251L may be formed to cover top and side surfaces of the bit line capping patterns 350, side surfaces of the bit lines BL, side surfaces of the bit line contacts DC, a top surface of a second buffer layer 250Lb, and the inner surfaces of the first recess regions RS1. The second insulating layer 253L may cover the first insulating layer 251L. The first and second insulating layers 251L and 253L may be formed of or include different materials from each other. In an implementation, the first insulating layer 251L may be formed of or include a silicon-containing insulating material (e.g., SiO, SiON, SiN, SiCN, or SiBN), the second insulating layer 253L may be formed of or include a metal-containing insulating material (e.g., lanthanum oxide (LaO) or scandium oxide (ScO)).

In an implementation, each of the first and second insulating layers 251L and 253L may have a constant thickness. In an implementation, the first and second insulating layers 251L and 253L may conformally cover the bit line capping patterns 350, the bit lines BL, the bit line contacts DC, and the inner surfaces of the first recess regions RS1. A thickness of the first insulating layer 251L may be larger than a thickness of the second insulating layer 253L, similar to the first and second insulating patterns 251 and 253 of FIG. 5A. The first and second insulating layers 251L and 253L may be formed to partially fill the first recess regions RS1.

In an implementation, the first insulating layer 251L may have a constant thickness, and the second insulating layer 253L may not have a constant thickness. The thickness of the second insulating layer 253L may be larger than the thickness of the first insulating layer 251L. Similar to the second insulating pattern 253 of FIG. 5B, the second insulating layer 253L may be provided to fully fill the first recess regions RS1.

In an implementation, the first and second insulating layers 251L and 253L may contain oxygen; e.g., the first insulating layer 251L may be formed of or include silicon oxide, and the second insulating layer 253L may be formed of or include a metal oxide. In this case, an oxygen density of the first insulating layer 251L may be higher than an oxygen density of the second insulating layer 253L.

Thereafter, a thermal treatment process may be performed on the first and second insulating layers 251L and 253L. As a result of the thermal treatment process, an electric dipole may be formed between the first and second insulating layers 251L and 253L. In an implementation, the electric dipole may be formed by a difference in oxygen density between the first and second insulating layers 251L and 253L. The thermal treatment process may be performed at a temperature of about 700° C. to about 1,000° C. for about 1 to about 30 seconds. In an implementation, the thermal treatment process may be omitted, and the electric dipole between the first and second insulating layers 251L and 253L may be formed by a subsequent process that is performed at a high temperature.

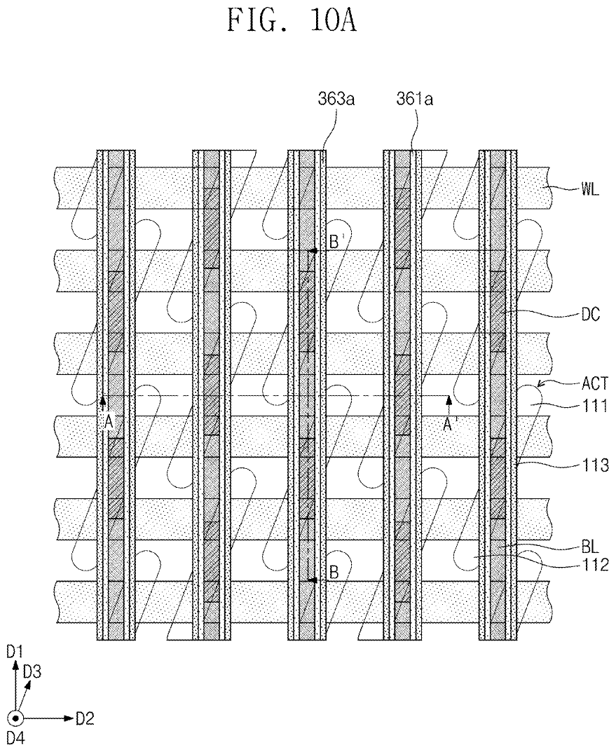

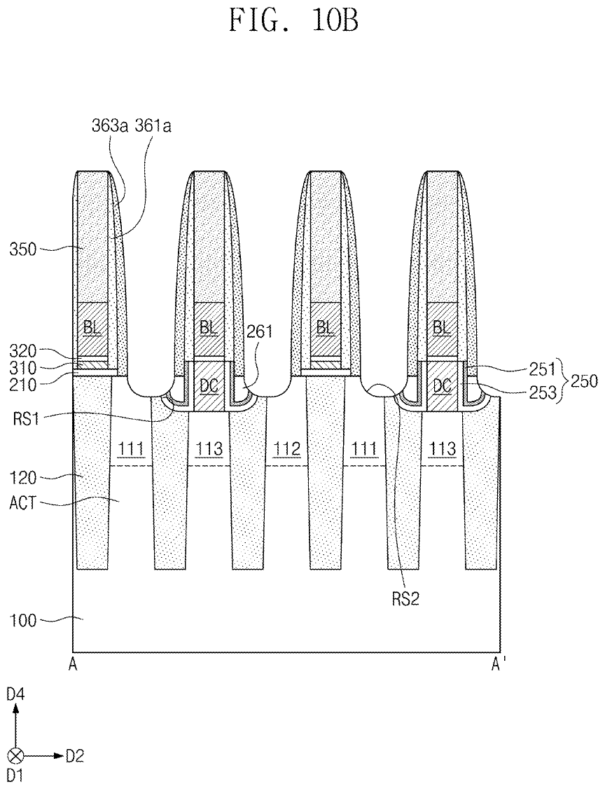

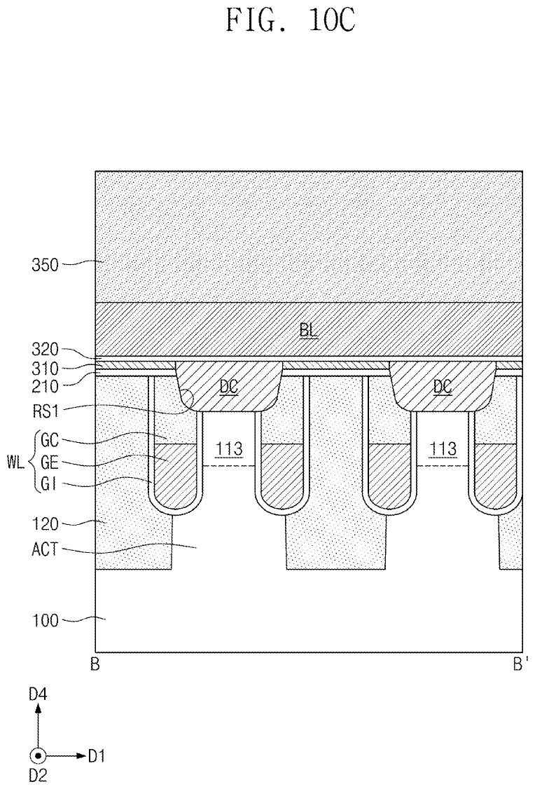

Referring to FIGS. 10A, 10B, and 10C, an insulating gapfill layer may be formed to fill remaining portions of the first recess regions RS1. The formation of the insulating gapfill layer may include depositing an insulating material on the second insulating layer 253L and removing the insulating material from the side surfaces of the bit lines BL and a top surface of the second buffer layer 210Lb. Accordingly, a top surface of the insulating gapfill layer may be formed at substantially the same level as the top surfaces of the edge portions 111 and 112 of the active patterns ACT.

Next, the first and second insulating layers 251L and 253L may be partially etched such that the top surfaces thereof are located at substantially the same level as the top surface of the bit line contact DC. Thus, the first and second insulating layers 251L and 253L may be removed from the side surfaces of the bit lines BL and the top and side surfaces of the bit line capping patterns 350. In an implementation, the side surfaces of the bit lines BL and the top and side surfaces of the bit line capping patterns 350 may be exposed to the outside.

First bit line spacer layers 361a may be formed on the exposed side surfaces of the bit lines BL and the exposed side surfaces of the bit line capping patterns 350, and then, the second buffer layer 210Lb may be partially removed using the first bit line spacer layers 361a. As a result of the partial removal of the second buffer layer 210Lb, the buffer pattern 210 may be formed from the second buffer layer 210Lb.

Second bit line spacer layers 363a may be formed on side surfaces of the first bit line spacer layers 361a, and then, an etching process may be performed using the second bit line spacer layers 363a. The etching process may be performed to partially remove the edge portions 111 and 112 of the active patterns ACT, the device isolation patterns 120, the insulating gapfill layer, and the first and second insulating layers 251L and 253L. As a result, the second recess region RS2 may be formed between the bit lines BL, which are adjacent to each other in the second direction D2. In addition, the insulating gapfill pattern 261 may be formed from the insulating gapfill layer, and the dipole formation structure 250 including the first and second insulating patterns 251 and 253 may be formed from the first and second insulating layers 251L and 253L. The edge portions 111 and 112 of the active patterns ACT, the device isolation patterns 120, the insulating gapfill patterns 261, and the dipole formation structures 250 may be exposed to the outside through the second recess regions RS2.

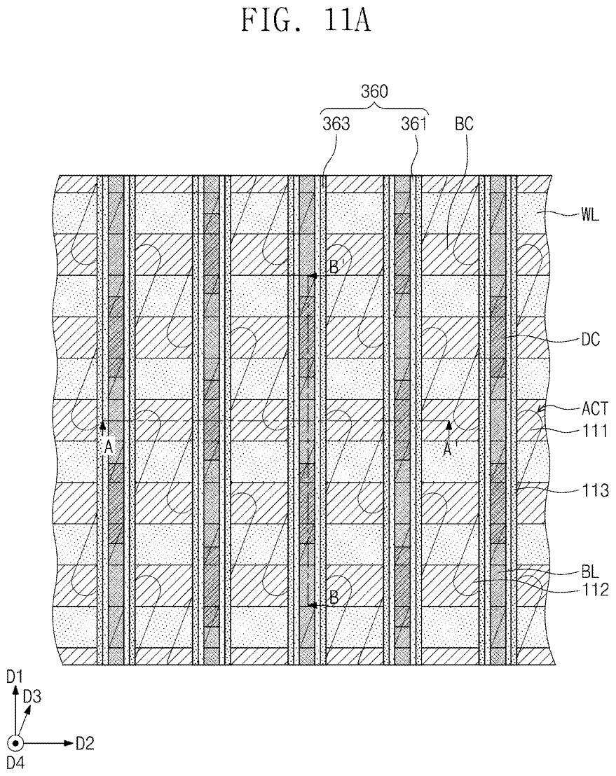

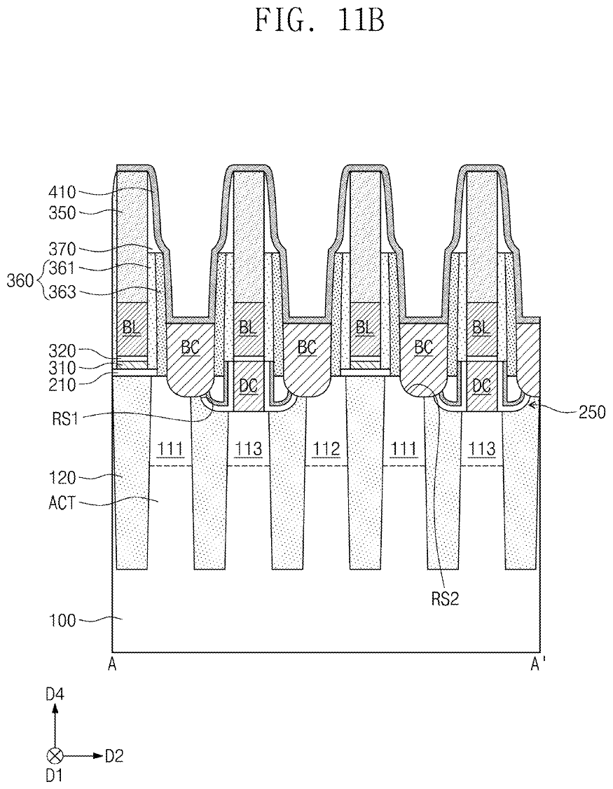

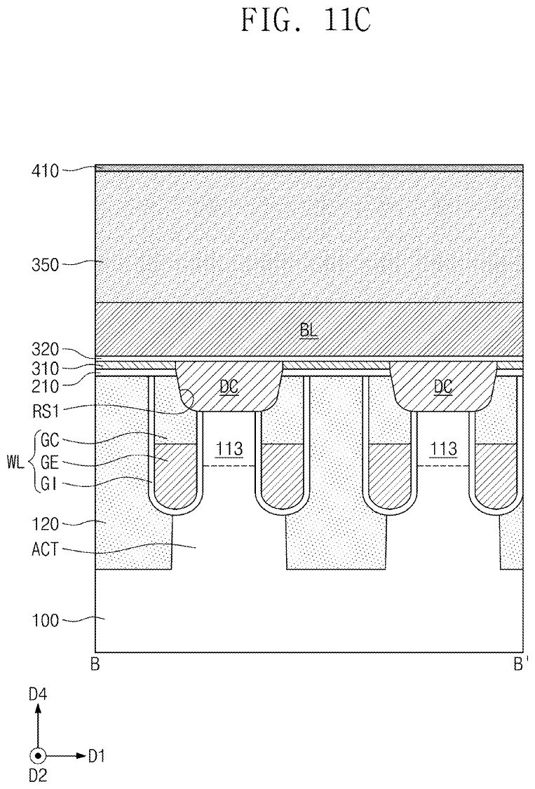

Referring to FIGS. 11A, 11B, and 11C, the storage node contacts BC may be formed between the bit lines BL, which are adjacent to each other in the second direction D2. The storage node contacts BC may be spaced apart from each other in the first and second directions D1 and D2. Each of the storage node contacts BC may be connected to a corresponding one of the edge portions 111 and 112 of the active patterns ACT. The formation of the storage node contacts BC may include forming storage node lines to fill the second recess regions RS2 and performing an etch-back process on the storage node lines.

In an implementation, the first and second bit line spacer layers 361a and 363a may be partially removed during the etch-back process. As a result, the first and second bit line spacer layers 361a and 363a may form the first and second bit line spacers 361 and 363, which constitute the bit line spacer 360. Next, the capping spacer 370 may be formed on the bit line spacer 360, and then, the second barrier pattern 410 may be formed to conformally cover the bit line spacer 360, the capping spacer 370, the storage node contacts BC, and the bit line capping patterns 350.

Referring back to FIGS. 3 and 4, the landing pads LP may be formed on the storage node contacts BC. The formation of the landing pads LP may include sequentially forming a landing pad layer and mask patterns to cover the top surfaces of the storage node contacts BC and performing an anisotropic etching process using the mask patterns as an etch mask to form a plurality of landing pads LP from the landing pad layer. In an implementation, the second barrier pattern 410, the bit line spacer 360, and the bit line capping pattern 350 may be partially etched through an etching process and may be exposed to the outside.

Next, the filler pattern 440 may be formed to cover the exposed portions of the second barrier pattern 410, the bit line spacer 360, and the bit line capping pattern 350 and enclose the side surfaces of the landing pads LP, and the data storage pattern DSP may be formed on each of the landing pads LP.

By way of summation and review, an integration density of the semiconductor device may be increased. As the integration density of the semiconductor device increases, the difficulty of the fabrication process for producing semiconductor devices may also increase. As a result, enhancing productivity in the fabrication process of the semiconductor devices has been considered.

According to an embodiment, a semiconductor device may include a dipole formation structure on a side surface of a bit line contact. The dipole formation structure may include a first insulating pattern and a second insulating pattern, and an electric dipole may be at an interface between the first and second insulating patterns. Accordingly, a width of a depletion region of the bit line contact may be reduced, and this may enable a relatively larger width for a current path for electrons. Accordingly, the electrical characteristics of the semiconductor device may be improved.

One or more embodiments may provide a semiconductor device with improved electrical and reliability characteristics.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a recess region;
a bit line contact in the recess region;
a bit line on the bit line contact, the bit line extending in a first direction;
a first insulating pattern covering side surfaces of the bit line contact and an inner surface of the recess region; and
a second insulating pattern on the first insulating pattern,
wherein an oxygen density of the first insulating pattern is higher than an oxygen density of the second insulating pattern.

2. The semiconductor device as claimed in claim 1, wherein the bit line contact includes doped poly silicon.

3. The semiconductor device as claimed in claim 1, further comprising an insulating gapfill pattern on the second insulating pattern,
wherein the insulating gapfill pattern fills the recess region, in which the first and second insulating patterns are formed.

4. The semiconductor device as claimed in claim 1, wherein the first and second insulating patterns extend on a side surface of the bit line.

5. The semiconductor device as claimed in claim 1, wherein:
the first and second insulating patterns are in contact with each other with an interface therebetween, and
an electric dipole is at the interface.

6. The semiconductor device as claimed in claim 1, wherein:
the first insulating pattern includes silicon oxide, and
the second insulating pattern includes a metal oxide.

7. A semiconductor device, comprising:
a substrate including an active pattern;
a bit line on the active pattern, the bit line extending in a first direction;
a bit line contact between the bit line and the active pattern;
a storage node contact on the active pattern and spaced apart from the bit line and the bit line contact; and
a dipole formation structure between a side surface of the bit line contact and the storage node contact, the dipole formation structure including a first insulating pattern and a second insulating pattern,
wherein the second insulating pattern includes a metal oxide.

8. The semiconductor device as claimed in claim 7, wherein the first insulating pattern is between the side surface of the bit line contact and the second insulating pattern.

9. The semiconductor device as claimed in claim 7, wherein a thickness of the first insulating pattern is larger than a thickness of the second insulating pattern.

10. The semiconductor device as claimed in claim 7, wherein the dipole formation structure extends on the side surface of the bit line.

11. The semiconductor device as claimed in claim 7, further comprising an insulating gapfill pattern between the dipole formation structure and the storage node contact,
wherein:
the first insulating pattern is in contact with the bit line contact, and
the second insulating pattern is in contact with the insulating gapfill pattern.

12. The semiconductor device as claimed in claim 7, wherein an oxygen density of the first insulating pattern is higher than an oxygen density of the second insulating pattern.

13. The semiconductor device as claimed in claim 7, wherein a length of the dipole formation structure in the first direction is substantially equal to a length of the bit line contact in the first direction.

14. The semiconductor device as claimed in claim 7, wherein:
the active pattern includes a center portion and edge portions, the edge portions being spaced apart from each other with the center portion therebetween,
the bit line contact is connected to the center portion, and
the storage node contact is connected to one of the edge portions.

15. The semiconductor device as claimed in claim 7, wherein the metal oxide includes lanthanum oxide or scandium oxide.

16. The semiconductor device as claimed in claim 7, further comprising:
a word line extending in a second direction and crossing the active pattern, the second direction intersecting the first direction; and
a data storage pattern connected to the storage node contact.

17. A semiconductor device, comprising:
active patterns, each active pattern including edge portions and a center portion between the edge portions;
bit lines on the center portions, the bit lines extending in a first direction;
bit line contacts between the center portions and the bit lines;
word lines extending in a second direction and crossing the active patterns, the second direction intersecting the first direction;
data storage patterns on the edge portions, respectively;
storage node contacts between the edge portions and the data storage patterns; and
dipole formation structures between side surfaces of the bit line contacts and the storage node contacts,
wherein:
each of the dipole formation structures includes a first insulating pattern and a second insulating pattern, which are in contact with each other,
the bit line contact includes doped poly silicon, and
the second insulating pattern includes a metal oxide.

18. The semiconductor device as claimed in claim 17, wherein:
the first insulating patterns are in contact with the side surfaces of the bit line contacts, and
an oxygen density of the first insulating pattern is higher than an oxygen density of the second insulating pattern.

19. The semiconductor device as claimed in claim 17, wherein an electric dipole is at an interface between the first and second insulating patterns.

20. The semiconductor device as claimed in claim 17, wherein the dipole formation structure extends on a side surface of the bit line.
